(19) United States
(12) Patent Application Publication
(10) Pub. No.: US 2014/0366932 A1
(43) Pub. Date: Dec. 18, 2014

(54) METHODS AND SYSTEMS FOR EVAPORATION CONTROL AND POWER PRODUCTION

(71) Applicant: SunEdison LLC, Beltsville, MD (US)

(72) Inventors: Rangachari Rajagopalan, Chennai (IN); Nagendra Cherukupalli, Cupertino, CA (US)

(21) Appl. No.: 14/361,846

(22) PCT Filed: Nov. 28, 2012
(86) PCT No.: PCT/US2012/066739

§ 371 Date: May 30, 2014

Related U.S. Application Data
(60) Provisional application No. 61/565,166, filed on Nov. 30, 2011.

(51) Int. Cl. H01L 31/042

(52) U.S. Cl. CPC H02S 30/00; H01L 31/0424
USPC 136/251

(57) ABSTRACT

An evaporation control system for an open liquid includes a photovoltaic (PV) panel and a mounting structure for supporting the PV panel. The PV panel is connected to the mounting structure such that the PV panel covers at least a portion of the liquid.

### CROSS-REFERENCE TO RELATED APPLICATIONS

This application claims priority to U.S. Provisional Application No. 61/565,166 filed Nov. 30, 2011, the entire disclosure of which is hereby incorporated by reference in its entirety.

### FIELD

The field of the present disclosure relates generally to photovoltaic power generation systems, and more specifically, to photovoltaic power generation systems configured to control evaporation on top of a liquid body (e.g., water canals).

### BACKGROUND

Photovoltaic arrays are devices that convert light energy into other forms of useful energy (e.g., electricity or thermal energy). One example of a photovoltaic array is a solar array that converts sunlight into electricity.

Evaporation from open channels, such as canals, streams, rivers and the like, is significant. Typically, to control evaporation, water is pumped through covered pipes. But this may be inefficient due to large power requirements to drive the pumps. Further, the pipes may be buried, which results in difficulty during maintenance of the piping due to having to uncover the piping to perform maintenance. A better system for controlling evaporation is needed.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION

In one aspect, an evaporation control system for an open liquid includes a photovoltaic (PV) panel and a mounting structure for supporting the PV panel. The PV panel is connected to the mounting structure such that the PV panel covers at least a portion of the liquid.

In another aspect, a method of controlling evaporation from an open body of liquid includes positioning one or more photovoltaic (PV) panels above the liquid to cover at least a portion of the liquid.

In yet another aspect, an evaporation control system includes photovoltaic panel and a mounting structure configured to support the PV panel over a body of liquid. A moisture return is configured to collect moisture that has deposited on the PV panel and transports the collected moisture to the body of liquid.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a perspective view of a photovoltaic array of an embodiment.

FIG. 2 is a cross-sectional view of the array of FIG. 1 taken along the line A-A of FIG. 1.

FIG. 3 is a perspective view of an array and an evaporation control system of an embodiment.

FIG. 4 is a side view of the evaporation control system of FIG. 3.

FIG. 5 is a side view of a wind breaker of an embodiment.

### DETAILED DESCRIPTION

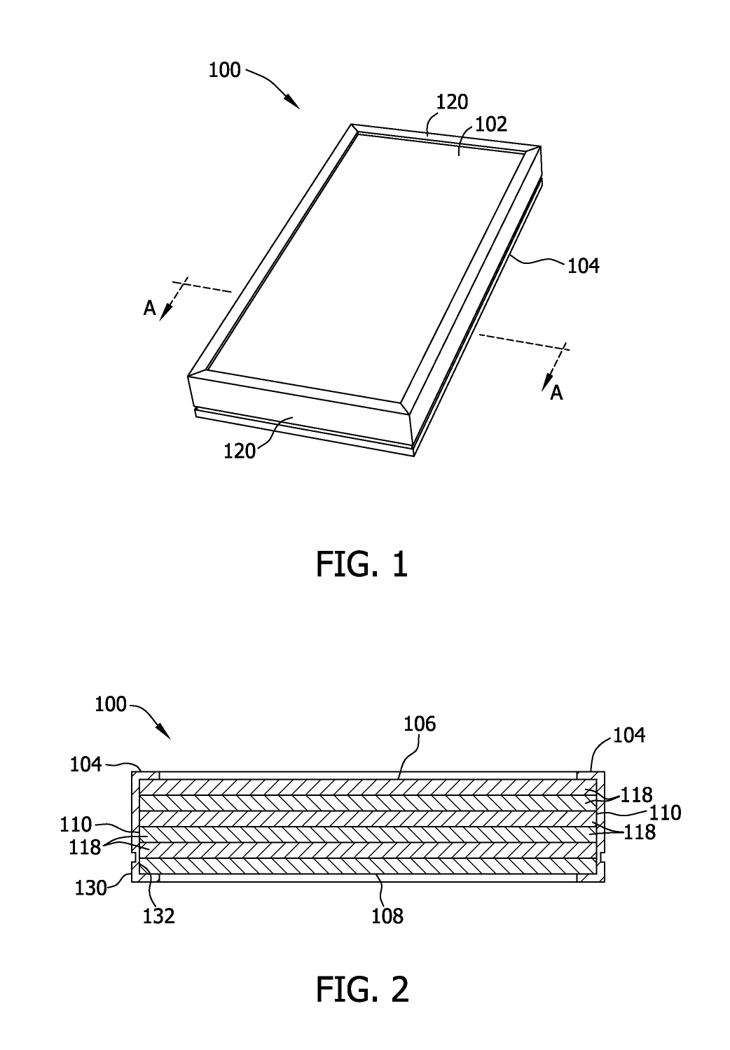

Referring to FIGS. 1-2, a photovoltaic panel of an embodiment is generally designated 100. Multiple modules 100 form a photovoltaic array. In this embodiment, the photovoltaic module 100 includes a solar panel 102. The solar panel 102 includes a frame 104, top surface 106 and a bottom surface 108. Edges 110 extend between top surface 106 and bottom surface 108. Solar panel 102 is rectangular-shaped. In other embodiments, solar panel 102 may have any shape that allows the photovoltaic module to function as described herein.

Frame 104 circumscribes and supports solar panel 102. Frame 104 is coupled to solar panel 102, for example as shown in FIG. 2. Frame 104 protects edges 110 of solar panel 102. Frame 104 includes an outer surface 130 spaced apart from solar panel 102 and an inner surface 132 adjacent to solar panel 102. In this embodiment, outer surface 130 is spaced apart from, and substantially parallel to, inner surface 132. In this embodiment, frame 104 is made of aluminum, such as 6000 series anodized aluminum, but the frame may be made of any suitable material providing sufficient rigidity including, for example, metal or metal alloys, plastic, fiberglass, carbon fiber and the like.

FIG. 2 is a cross-sectional view of photovoltaic module 100 taken at line A-A shown in FIG. 1. In this embodiment, solar panel 102 has a laminate structure that includes a plurality of layers 118. Layers 118 include, for example, glass layers, non-reflective layers, electrical connection layers, n-type silicon layers, p-type silicon layers, backing layers and combinations thereof In other embodiments, solar panel 102 may have more or fewer layers 118 than shown in FIG. 2, including only one layer.

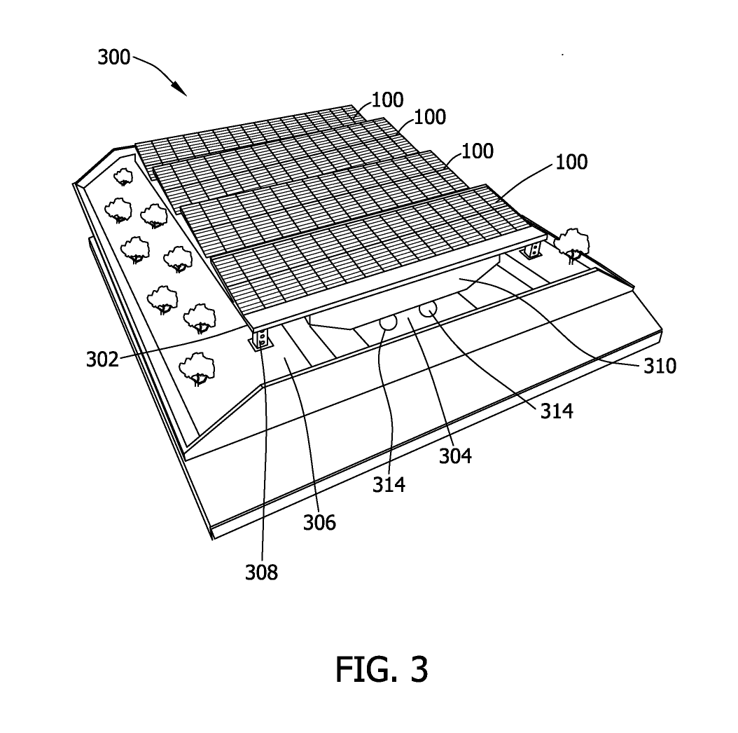

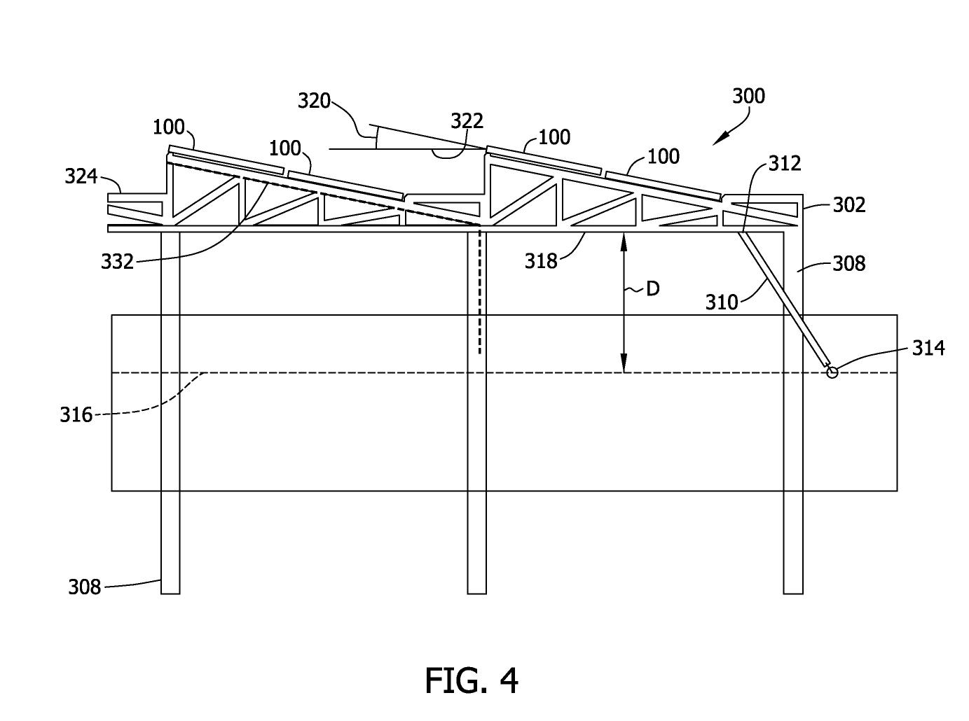

FIG. 3 is a perspective view of an evaporation control system 300. The evaporation control system includes a photovoltaic assembly of photovoltaic modules 100 and a mounting structure 302 for supporting the photovoltaic assembly. In the illustrated embodiment, the photovoltaic assembly includes four photovoltaic modules 100. In other embodiments, the photovoltaic assembly may include more or fewer photovoltaic module 100 and/or solar panels 102. The mounting structure 302 supports photovoltaic module 100 over at least a portion of an open body of liquid 304. By positioning photovoltaic module 100 over liquid 304, evaporation is controlled by providing shade and providing a cover over liquid 304.

In example embodiments, liquid 304 is a pond, lake, canal, stream, creek, river, viaduct or the like. Liquid 304 may include potable water, non-potable water, salt water, freshwater, liquid chemicals or any other liquid.

In this embodiment, support structure 302 is attached to a bank 306 of the open body of liquid 304 by footings 308. In other embodiment, footings 306 may be positioned within the liquid 304. In some embodiments, support structure 302 is made of metal, metal alloys, fiberglass, carbon fiber, plastic and the like or combinations thereof

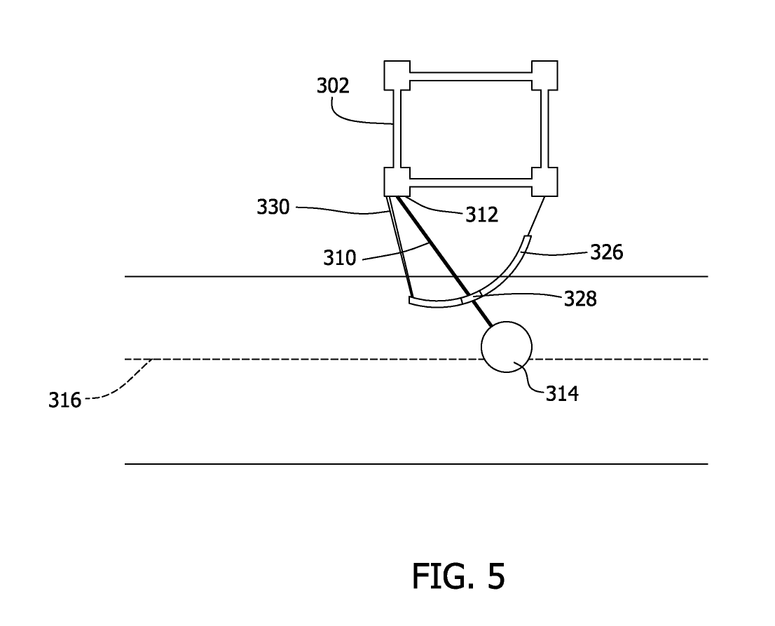

Evaporation control system 300 includes a wind breaker 310. Wind breaker 310 is configured to limit airflow between photovoltaic module 100 and liquid 304. Wind breaker 310 thus facilitates a reduction in an amount of evaporated moisture that is carried away by wind, for example by blocking a portion of the wind and/or reducing a speed of the wind over liquid 304. Wind breaker 310 is suitably made of metal, metal alloys, fiberglass, carbon fiber, plastic and the like or combinations thereof In this embodiment, wind breaker is hingedly attached to support structure 302 by hinge 312 (shown in FIG. 4). In this embodiment, wind breaker 310 is also supported by two floats 314. In other embodiments, wind breaker 310 may be supported solely by floats 314, may be coupled mounting structure 302 without floats 314, may be supported by more or fewer floats 314, and/or may be coupled to structure 302 in any other suitable manner. The floats 314 are configured to support wind breaker 310 at a lower portion of wind breaker 310, thus maintaining wind breaker 310 above a level 316 (shown in FIGS. 4 and 5) of liquid 304 so as not to hinder the flow of liquid 304. Floats 314 are configured to maintain the wind breaker 310 above level 316 even as the level 316 changes over time, thus limiting the wind flowing over liquid 304 even if level 316 changes.

In this embodiment, evaporation control system 300 includes a plurality of wind breakers 304. A first wind breaker 310 is positioned at an upstream position of the liquid 304 and a second one of the wind breakers 310 is positioned at a downstream position of the liquid 304. Other embodiments may include more or fewer wind breakers 310.

A lower portion 318 of support structure 302 is positioned at a predetermined distance D (shown in FIG. 4) above level 316 of liquid 304. For example, the support structure is disposed at a position close enough to the liquid that evaporation is controlled yet high enough above the level 316 of liquid 304 to provide access to photovoltaic modules 100 for maintenance. In some embodiments, the lower portion 318 is positioned between about 0.5 m to about 4 m above liquid level 316, for example 1 m.

In some embodiments, support structure 302 is configured to support one or more photovoltaic modules 100 at a nonzero angle 320 relative to a horizontal plane 322. In other embodiments, support structure 302 includes an adjustment device (not shown) configured to adjust angle 320, for example, for solar tracking.

Support structure 302 includes a walkway 324 extending along all or a part of a longitudinal length of support structure 302 or a length of support structure 302 that is angled relative to the longitudinal length. Walkway 320 is sized and configured to allow a worker to access one or more of photovoltaic modules 100, for example for maintenance operations.

Wind breaker 310 is connected to a restrictor 326 (shown in FIG. 5). In this embodiment, restrictor 326 is a curved track, though the restrictor may be straight or absent in other embodiments. Wind breaker 310 is movably connected to restrictor 326 by connectors 328. In some embodiments, connectors 328 are rollers, slides, bearings or the like. Restrictor 326 is connected to support structure 302 via restrictor supports 330. In some embodiments, restrictor supports 330 include cables. In other embodiments, restrictor supports 330 may include rigid beams, semi-rigid beams, and/or any other suitable supports.

One or more returns 332 are positioned to collect moisture that has evaporated, and collected on support structure 302 and/or photovoltaic modules 100. The return is configured to collect the moisture and transport the moisture back to liquid 304. In some embodiments, returns 332 are gutters, channels tubes, and/or any other suitable structure for directing the flow of fluid.

In some embodiments, one or more of photovoltaic modules 100 are connected to and configured to supply power to an electrical power grid (not shown).

The methods and systems described herein may facilitate controlling liquid evaporation while producing power by using photovoltaic panels. In some embodiments, evaporation is further reduced by controlling an amount of wind passing over the liquid by using a wind breaker. In other embodiments, the photovoltaic panels are located close enough to the liquid to ensure that evaporation is controlled, but at a height above the liquid that provides access for maintenance by use of a walkway.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above apparatus and methods without departing from the scope of the disclosure, it is intended that all matter contained in the above description and shown in the accompanying figures shall be interpreted as illustrative and not in a limiting sense.

What is claimed is:

1. An evaporation control system for an open body of liquid, comprising:
a photovoltaic (PV) panel assembly; and
a mounting structure configured to support the PV panel assembly above the body of liquid with the PV panel assembly covering at least a portion of the body of liquid.

2. The evaporation control system according to claim 1, further comprising a wind breaker configured to limit airflow between the PV panel assembly and the body of liquid.

3. The evaporation control system according to claim 2, further comprising a float coupled to the wind breaker, the float configured to support the wind breaker above a level of the body of liquid.

4. The evaporation control system according to claim 1, wherein the mounting structure is configured to span a width of the body of liquid.

5. The evaporation control system according to claim 1, wherein the PV panel assembly comprises a plurality of PV panels.

6. The evaporation control system according to claim 5, wherein the mounting structure is configured to support the PV panels at an angle relative to a horizontal plane.

7. The evaporation control system according to claim 6, wherein the mounting structure comprises an adjustable member configured to adjust the angle.

8. The evaporation control system according to claim 6, wherein the mounting structure comprises a fixed member configured to support the PV panels at a predetermined angle relative to the horizontal plane.

9. The evaporation control system according to claim 1, further comprising a walkway connected to the mounting structure.

10. The evaporation control system according to claim 1, wherein the mounting structure is configured to support the PV panel assembly above a water canal with the PV panel assembly covering at least a portion of the water canal.

11. A method of controlling evaporation from an open body of liquid, comprising:
positioning a photovoltaic (PV) panel assembly above the body of liquid with the PV panel assembly covering at least a portion of the body of liquid; and
positioning a wind breaker between the liquid and the PV panel assembly.

12. The method according to claim 11, further comprising supporting the wind breaker with a float.

13. The method according to claim 11, further comprising generating electrical power with the PV panel assembly.

14. The method according to claim 11, wherein positioning a PV panel assembly above the body of liquid positioning a PV panel assembly including a plurality of PV panels above the body of liquid.

15. An evaporation control system, comprising:
a array of photovoltaic (PV) panels;
a mounting structure configured to support the array over an open body of liquid;
a moisture return configured to collect moisture deposited on the array and transport the collected moisture to the body of liquid.

16. The evaporation control system according to claim 15, further comprising a wind breaker disposed between the open body of liquid and the array.

17. The evaporation control system according to claim 16, further comprising a float coupled to the wind breaker and configured to support the wind breaker above a level of the liquid.

18. The evaporation control system according to claim 15, further comprising a walkway coupled to the mounting structure.

19. The evaporation control system according to claim 15, wherein the mounting structure is configured to support the PV panels at one or more angles relative to a horizontal plane.

20. The evaporation control system according to claim 19, wherein the mounting structure comprises an adjustable member configured to adjust the angle of at least one of the PV panels relative to the horizontal plane.

21. The evaporation control system according to claim 19, wherein the mounting structure comprises a fixed member configured to support at least one of the PV panels at a predetermined angle relative to the horizontal plane.
